(19) United States
(12) Patent Application Publication
(10) Pub. No.: US 2026/0033153 A1
(43) Pub. Date: Jan. 29, 2026

(54) DISPLAY PANEL AND DISPLAY DEVICE

(71) Applicants: KunShan Go-Visionox Opto-Electronics Co., Ltd., Kunshan (CN); Hefei Visionox Technology Co., Ltd., Hefei (CN)

(72) Inventors: Chung-Chun LEE, Kunshan (CN); Bo RAO, Hefei (CN); Yuan YAO, Hefei (CN); Peng QIN, Kunshan (CN)

(73) Assignees: KunShan Go-Visionox Opto-Electronics Co., Ltd., Kunshan (CN); Hefei Visionox Technology Co., Ltd., Hefei (CN)

(21) Appl. No.: 19/271,682

(22) Filed: Jul. 16, 2025

(30) Foreign Application Priority Data
Jul. 26, 2024 (CN) 202411011723.1

(51) Int. Cl. H10K 59/122; H10K 59/40

(52) U.S. Cl. CPC H10K 59/122; H10K 59/40

(57) ABSTRACT

Embodiments of the present disclosure provide a display panel and a display device. The display panel includes an array substrate, an isolation structure and a touch layer, where the isolation structure is disposed on one side of the array substrate, a plurality of isolation openings and a plurality of first openings are formed in the isolation structure, and the first openings are distributed in the first active area; and the touch layer is disposed on a side of the isolation structure facing away from the array substrate, the touch layer includes a plurality of touch meshes, and the orthographic projections of the touch meshes in the first active area on the array substrate form the same patterns as the orthographic projections of the touch meshes in the second active area on the array substrate, make the display effect of the first active area consistent with the second active area.

### CROSS REFERENCE TO RELATED APPLICATION

The present application claims priority to Chinese Patent Application No. 202411011723.1 filed on Jul. 26, 2024, which is incorporated herein by reference in its entirety.

### FIELD

The present disclosure relates to the field of display equipment, and particularly to a display panel and a display device.

### BACKGROUND

Display panels, such as a liquid crystal display (LCD) panel, an organic light-emitting diode (OLED) display panel, and a display panel using a light-emitting diode (LED) device, are widely applied to various electronic products such as mobile phones, televisions, personal digital assistants, digital cameras, laptop computers and desktop computers thanks to their advantages such as high image quality, energy efficiency, slim design and a wide range of applications.

In the related art, a light sensor is disposed on one side of a display panel and can receive light transmitted through the display panel, and an area corresponding to the light sensor and an area not corresponding to the light sensor are differentiated in order to increase the light transmitted through the display panel, which allows the two areas to be different in color shift.

### SUMMARY

Embodiments of the present disclosure provide a display panel and a display device, and aim to reduce a color shift difference of the display panel.

According to a first aspect, an embodiment of the present disclosure provides a display panel. The display panel includes a first active area and a second active area, and a light transmittance of the first active area is greater than a light transmittance of the second active area. The display panel includes:
an array substrate;
an isolation structure disposed on one side of the array substrate, a plurality of isolation openings and a plurality of first openings being formed in the isolation structure, and the first openings being distributed in the first active area;
a light-emitting functional layer including a plurality of light-emitting units, at least part of the light-emitting unit being disposed in the corresponding isolation opening; and
a touch layer disposed on a side of the isolation structure facing away from the array substrate, the touch layer including a plurality of touch meshes, where orthographic projections of the touch meshes on the array substrate do not overlap with orthographic projections of the light-emitting units on the array substrate, and orthographic projections of the touch meshes in the first active area on the array substrate form the same patterns as orthographic projections of the touch meshes in the second active area on the array substrate.

According to a second aspect, an embodiment of the present disclosure provides a display panel. The display panel includes:
an array substrate;
an isolation structure disposed on one side of the array substrate, a plurality of isolation openings and a plurality of first openings being formed in the isolation structure;
a light-emitting functional layer including a plurality of light-emitting units, at least part of the light-emitting unit being disposed in the corresponding isolation opening; and
a touch layer disposed on a side of the isolation structure facing away from the array substrate, the touch layer including a plurality of touch meshes, where orthographic projections of the touch meshes on the array substrate do not overlap with orthographic projections of the light-emitting units on the array substrate, and orthographic projections of the touch meshes in the first active area on the array substrate partially overlap with an orthographic projection of at least one first opening on the array substrate.

According to a third aspect, an embodiment of the present disclosure provides a display device, including a display panel of any one of the above embodiments in the first aspect or the second aspect.

In the display panel and the display device provided in the embodiments of the present disclosure, the light transmittance of the first active area is improved by providing the first openings; and by setting the orthographic projection of the touch mesh located in the second active area and the orthographic projection of the touch mesh located in the first active area to form the same patterns, the effects of the first active area and the second active area in a display state and a non-display state are consistent, and a color shift phenomenon of the display panel is avoided or reduced.

### BRIEF DESCRIPTION OF THE DRAWINGS

In order to describe the embodiments of the present disclosure more clearly, the drawings required for illustration of the embodiments of the present disclosure will be briefly introduced below. The drawings as described below are only for some of the embodiments of the present disclosure.

FIG. 1 is a structural schematic plan view of a display panel according to some embodiments of the present disclosure;

FIG. 2 is a structural schematic partial plan view of a display panel according to some embodiments of the present disclosure;

FIG. 3 is a structural schematic partial cross-sectional view of a first active area of a display panel according to some embodiments of the present disclosure;

FIG. 4 is a structural schematic partial plan view of a display panel according to some embodiments of the present disclosure;

FIG. 5 is a structural schematic partial plan view of a first sub-opening and a touch mesh according to some embodiments of the present disclosure;

FIG. 6 is a structural schematic partial plan view of a display panel according to some embodiments of the present disclosure;

FIG. 7 is a structural schematic partial plan view of a display panel according to some embodiments of the present disclosure;

FIG. 8 is a structural schematic partial plan view of a display panel according to some embodiments of the present disclosure; and

FIG. 9 is a structural schematic partial cross-sectional view of a first active area of a display panel according to some embodiments of the present disclosure.

### LIST OF REFERENCE SIGNS

AA1. First active area; AA2. Second active area;
100. Display panel; 1. Array substrate; 11. Base substrate; 12. Drive circuit layer;
2. Isolation structure; 21. First isolation layer; 22. Second isolation layer; 23. Isolation opening; 23a. First isolation opening; 23b. Second isolation opening; 23c. Third isolation opening; 24. First opening; 24a. First sub-opening; 24b. Second sub-opening; 24c. Third sub-opening; 25. Third isolation layer;
31. Light-emitting unit; 31a. First light-emitting unit; 31b. Second light-emitting unit;
31c. Third light-emitting unit; 33. First electrode; 34. Light-emitting layer; 35. Second electrode;
4. Touch layer; 41. Touch mesh;
8. Pixel defining layer; 81. Pixel opening;
X. First direction; Y. Second direction; Z. Third direction.

### DETAILED DESCRIPTION OF THE EMBODIMENTS

Features and exemplary embodiments in various aspects of the present disclosure will be described in detail below. In order to make the embodiments of the present disclosure clearer, the present disclosure will be further described in detail below with reference to the accompanying drawings and embodiments. It should be understood that the embodiments described herein are merely configured to explain the present disclosure and are not configured to limit the present disclosure. The present disclosure may be implemented without some of these specific details. The following description of the embodiments is merely to provide a better understanding of the present disclosure by illustrating examples of the present disclosure.

It should be noted that, herein, relative terms such as “first” and “second” are only used to distinguish one entity or operation from another entity or operation, and do not necessarily require or imply that such an actual relationship or order exists between these entities or operations. Moreover, the terms “include”, “comprise”, or any other variants thereof are intended to cover a non-exclusive inclusion, so that a process, a method, an article, or a device that includes a list of elements not only includes those elements but also includes other elements that are not listed, or further includes elements inherent to such a process, method, article, or device. If no more limitations are made, an element limited by “comprising/including . . . ” does not exclude other identical elements existing in the process, the method, the article, or the device which includes the element.

It should be understood that in the description of the structure of a component, a layer or region referred as being located “above” or “over” another layer or region may be directly on the other layer or region, or there may be other layers or regions between the layer or region and the other layer or region. Moreover, if the component is turned over, the layer or region is located “below” or “under” the other layer or region.

In the related art, a light sensor is disposed on one side of a display panel and can receive light transmitted through the display panel, and an area corresponding to the light sensor and an area not corresponding to the light sensor are differentiated in order to increase the light transmitted through the display panel, which allows the two areas to be different in color shift in an always-on state.

In order to solve the above problem, the embodiments of the present disclosure provide a display panel and a display device. Various embodiments of the display panel and the display device will be described below with reference to the drawings.

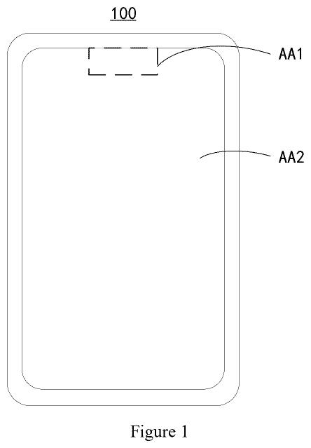

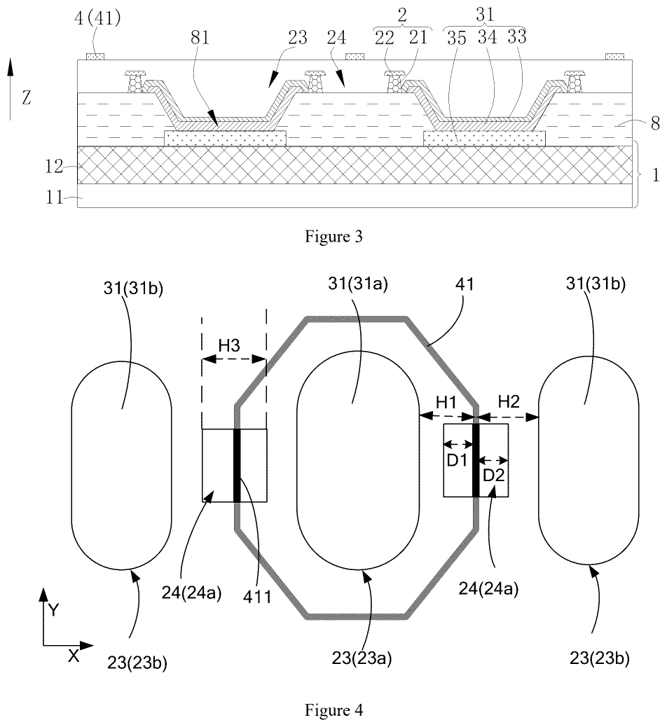

According to a first aspect, the present disclosure provides a display panel. As shown in FIGS. 1, 2, 3 and 4, a display panel 100 includes a first active area AA1 and a second active area AA2, where a light transmittance of the first active area AA1 is greater than a light transmittance of the second active area AA2; the display panel 100 includes an array substrate 1, an isolation structure 2, a light-emitting functional layer and a touch layer 4, where the isolation structure 2 is disposed on one side of the array substrate 1, a plurality of isolation openings 23 and a plurality of first openings 24 are formed in the isolation structure 2, and the first openings 24 are distributed in the first active area AA1; the light-emitting functional layer includes a plurality of light-emitting units 31, and at least part of the light-emitting unit 31 is disposed in the isolation opening 23; and the touch layer 4 is disposed on a side of the isolation structure 2 facing away from the array substrate 1, the touch layer 4 includes a plurality of touch meshes 41, orthographic projections of the touch meshes 41 on the array substrate 1 do not overlap with orthographic projections of the light-emitting units 31 on the array substrate 1, and the orthographic projections of the touch meshes 41 in the first active area AA1 on the array substrate 1 form the same patterns as the orthographic projections of the touch meshes 41 in the second active area AA2 on the array substrate 1.

The display panel 100 provided in the embodiments of the present disclosure may be a display panel 100 based on an organic light-emitting diode (OLED) technology. For the isolation structure 2, reference can be made to the relevant descriptions in Chinese patents CN 118251982 A, 202410864269.8, PCT/CN 2024/098407, PCT/CN 2024/102783, PCT/CN 2024/098217, PCT/CN 2024/100935, PCT/CN 2024/102785, PCT/CN 2024/099419, PCT/CN 2024/099072, and CN 116685174 A.

The display panel 100 includes a first active area AA1 and a second active area AA2, and a plurality of first openings 24 are distributed in the first active area AA1. For example, the plurality of first openings 24 are distributed only in the first active area AA1. For another example, the plurality of first openings 24 are distributed not only in the first active area AA1, but also in the second active area AA2, the first openings 24 located in the first active area AA1 have a distribution density greater than a distribution density of the first openings 24 located in the second active area AA2, or the plurality of first openings 24 are arranged in the first active area AA1 in the same manner as the plurality of first openings 24 arranged in the second active area AA2, and a projection area of the plurality of first openings 24 in the first active area AA1 on the array substrate 1 is greater than a projection area of the plurality of first openings 24 in the second active area AA2 on the array substrate 1. The first openings 24 are disposed in the first active area AA1 to improve the light transmittance of the first active area AA1.

An active area AA is configured to achieve picture display, the active area AA includes the first active area AA1 and the second active area AA2, and compared with the second active area AA2, the first active area AA1 may also be configured to transmit light into an optical sensor. The first active area AA1 may be an active area below which an optical sensor is disposed. The optical sensor may be a fingerprint recognition sensor or an infrared sensor. The first active area AA1 may be an aperture area of the display panel 100, and relevant components may be disposed under a screen of the first active area AA1. For example, the optical sensor may be disposed, and the optical sensor receives the light transmitted through the first active area AA1. In one embodiment, the optical sensor may be an infrared sensor, a fingerprint recognition sensor, etc.

In the display panel 100 provided in the embodiments of the present disclosure, the array substrate 1 may not only provide a supporting force for the isolation structure 2, but also provide electrical signals for the light-emitting functional layer and the touch layer 4. The array substrate 1 may be configured in various forms. In some embodiments, the array substrate 1 may include a base substrate 11 and a drive circuit layer 12 disposed on the base substrate 11, the base substrate 11 may be a silicon substrate, and a flexible substrate 11 may also be employed, for example, polyimide. The drive circuit layer 12 may include a pixel drive circuit, a plurality of stacked conductive connecting structures, a plurality of driving units, etc. For example, the pixel drive circuit disposed in the drive circuit layer 12 includes a transistor and a storage capacitor. For example, each driving unit may include one or more semiconductor switching elements. The semiconductor switching element may be formed collectively by a plurality of film layers in the array substrate 1. For example, the semiconductor switching element may be a thin film transistor formed collectively by the plurality of film layers.

The isolation structure 2 defines a plurality of isolation openings 23, and the plurality of first openings 24 are formed in the isolation structure 2. The isolation opening 23 is configured to limit the light-emitting unit 31, and at least part of the light-emitting unit 31 is located in the isolation opening 23, that is, an orthographic projection of at least part of the light-emitting unit 31 on the array substrate 1 is located within an orthographic projection of the isolation opening 23 on the array substrate 1. The number of the isolation openings 23 may be in one-to-one correspondence with the number of the light-emitting units 31, or a plurality of light-emitting units 31 are disposed in one isolation opening 23.

The light-emitting units 31 are distributed in the first active area AA1 and the second active area AA2, such that both the first active area AA1 and the second active area AA2 can display light. The plurality of light-emitting units 31 may be light-emitting units 31 capable of emitting light of different colors. For example, the plurality of light-emitting units may be a red light-emitting unit capable of emitting red light, a green light-emitting unit capable of emitting green light, and a blue light-emitting unit capable of emitting blue light. The number of the isolation openings 23 and the number of the first openings 24 may be determined as required. For example, 1 red light-emitting unit, 2 green light-emitting units and 1 blue light-emitting unit are respectively located in 4 isolation openings 23 to form a pixel light-emitting group 31G, and the pixel light-emitting groups 31G are arranged in an array in a first direction X and a second direction Y; and in one pixel light-emitting group 31G, two green light-emitting units may be spaced apart in the first direction X, and the red light-emitting unit and the blue light-emitting unit may be spaced apart in the first direction X. In a plurality of arranged pixel light-emitting groups 31G, the red light-emitting units and the blue light-emitting units are alternately disposed at intervals in the first direction X to form a first pixel row, a plurality of green light-emitting units are alternately disposed at intervals in the first direction X to form a second pixel row, and the first pixel row and the second pixel row are arranged alternately in the second direction Y. Patterns formed by the orthographic projections of the light-emitting units 31 on the array substrate 1 may be polygonal patterns, elliptical patterns, or irregular patterns having arc-shaped sides. The irregular pattern with arc-shaped sides may have oppositely disposed straight sides and oppositely disposed arc-shaped sides, and the oppositely disposed arc-shaped sides are respectively connected to two straight sides.

The first opening 24 may be a light-transmitting opening. An orthographic projection of the first opening 24 on the array substrate 1 is configured to not overlap with an orthographic projection of the light-emitting unit 31 on the array substrate 1, so that ambient light is not shielded by the light-emitting unit 31 and thus can pass through the first opening 24 smoothly. The first openings 24 may be disposed completely or mainly in the first active area AA1, and the ambient light may be irradiated to the optical sensor through the first openings 24.

The touch layer 4 allows a touch operation to be performed on the display panel 100. The touch layer 4 may be disposed on a light exit side of the light-emitting functional layer. To prevent the touch layer 4 from affecting the display of the light-emitting functional layer, the touch layer 4 may be made of a light-transmitting material. The touch layer 4 may be a mesh electrode film based on a metal-mesh capacitive touch technology (Metal Mesh). The touch layer 4 may include touch meshes 41, each touch mesh 41 may include one or more conductive traces, and the one or more conductive traces form the patterned touch mesh 41. The touch mesh 41 may be prepared by means of an exposure etching technique. The conductive traces in the touch mesh 41 may be connected or be disconnected by a break, and the conductive traces on two sides of the break may be used respectively as a driving electrode and a sensing electrode mutually capacitive to collect touch signals. The adjacent touch meshes 41 may also be disconnected by a break, such that the adjacent touch meshes 41 may be used respectively as a driving electrode and a sensing electrode mutually capacitive to collect touch signals. The plurality of touch meshes 41 are arranged in the display panel 100, such that the display panel 100 can have a touch function. The touch mesh 41 has mesh holes, and the light-emitting units 31 can be exposed from the mesh holes, such that orthographic projections of the touch meshes 41 on the array substrate 1 do not overlap with the orthographic projections of the light-emitting units 31 on the array substrate 1, avoiding or reducing the effect of the conductive traces in the touch meshes 41 on the light emergence of the light-emitting units 31. Orthographic projections of all or part of the conductive traces in one touch mesh 41 on the array substrate 1 may surround a peripheral side of an orthographic projection of one light-emitting unit 31 on the array substrate 1, and may also surround at least part of an orthographic projection of one light-emitting unit 31 on the array substrate 1. One touch mesh 41 may correspond to one pixel light-emitting group 31G or one light-emitting unit 31, and a plurality of touch meshes 41 are arranged in an array in the first direction X and the second direction Y.

The “orthographic projection” described in the present disclosure may be a projection in a third direction Z, and the third direction Z may be a thickness direction of the display panel 100, or a direction from the array substrate 1 to the light-emitting functional layer.

The touch meshes 41 may be distributed in the first active area AA1 and the second active area AA2, such that both the first active area AA1 and the second active area AA2 can achieve touch control. The orthographic projections of the touch meshes 41 in the first active area AA1 on the array substrate 1 form the same patterns as the orthographic projections of the touch meshes 41 in the second active area AA2 on the array substrate 1, and the patterns being the same means that the touch mesh 41 of an enclosure mesh located in the second active area AA2 forms the same pattern as the touch mesh 41 of an enclosure mesh located in the first active area AA1. The pattern formed by the orthographic projection of the touch mesh 41 on the array substrate 1 may be a closed pattern or an unclosed pattern.

In this embodiment, the light transmittance of the first active area AA1 is improved by providing the first openings 24; and by setting the orthographic projection of the touch mesh 41 located in the second active area AA2 and the orthographic projection of the touch mesh 41 located in the first active area AA1 to form the same patterns, the effects of the first active area AA1 and the second active area AA2 in a display state and a non-display state are consistent, and a color shift phenomenon of the display panel 100 is avoided or reduced.

In some embodiments, the plurality of first openings 24 include a plurality of first sub-openings 24a, and the orthographic projections of the touch meshes 41 located in the first active area AA1 on the array substrate 1 partially overlap with the orthographic projections of the first sub-openings 24a on the array substrate 1.

The display panel 100 may be provided with only the first sub-openings 24a therein, or may be provided with other first openings 24 other than the first sub-openings 24a, and different sub-openings have different projection areas and setting rules.

The orthographic projections of the touch meshes 41 located in the first active area AA1 on the array substrate 1 partially overlap with the orthographic projections of the first sub-openings 24a on the array substrate 1, that is, the touch meshes 41 partially shield the first sub-openings 24a, such that part of the light irradiated into the display panel 100 is shielded by the touch meshes. In order to ensure that the orthographic projections of the touch meshes 41 in the first active area AA1 on the array substrate 1 form the same patterns as the orthographic projections of the touch meshes 41 in the second active area AA2 on the array substrate 1, the touch meshes 41 disposed in the first active area AA1 can shield part of the first sub-openings 24a.

In some embodiments, the plurality of isolation openings 23 include a first isolation opening 23a and a second isolation opening 23b; and the first sub-opening 24a is disposed between the first isolation opening 23a and the second isolation opening 23b which are adjacent in the first direction X.

The light emitted by the light-emitting units 31 received into the first isolation opening 23a and the second isolation opening 23b may have the same or different colors. For example, the plurality of light-emitting units 31 include a first light-emitting unit 31a for emitting first color light and a second light-emitting unit 31b for emitting second color light, at least part of the first light-emitting unit 31a is located within the first isolation opening 23a, at least part of the second light-emitting unit 31b is located within the second isolation opening 23b, and the first color light and the second color light may respectively be one of blue light, red light and green light. Optionally, the first color light may be blue light, the second color light may be red light, the first light-emitting unit 31a is configured to emit blue light, and the second light-emitting unit 31b is configured to emit red light. The plurality of first light-emitting units 31a and the plurality of second light-emitting units 31b may be alternately disposed in the first direction X, and the plurality of first sub-openings 24a may be sequentially disposed at intervals in the first direction X and located between the first light-emitting units 31a and the second light-emitting units 31b which are adjacent, such that the ambient light can be incident from one side of the display panel 100 through the first sub-openings 24a between the first light-emitting units 31a and the second light-emitting units 31b.

In some embodiments, the orthographic projection of the touch mesh 41 located in the first active area AA1 on the array substrate 1 includes a first projection, the orthographic projection of the first sub-opening 24a on the array substrate 1 is a second projection, and the first projection is located within the second projection; and
there is a distance H1 from the first projection to the first isolation opening 23a, and there is a distance H2 from the first projection to the second isolation opening 23b, where H1 is equal to H2.

The orthographic projection of the touch mesh 41 on the array substrate 1 further includes other projections apart from the first projection, and the first projection is part of the orthographic projection of the touch mesh 41 on the array substrate 1. The orthographic projection of a first conductive segment 411 in the touch mesh 41 on the array substrate 1 is the first projection, and orthographic projections, on the array substrate 1, of other traces in the touch mesh 41 apart from the first conductive segment 411 may be connected to or spaced apart from the first projection.

The orthographic projection of the first sub-opening 24a on the array substrate 1 is a second projection, the first projection is located within the second projection, that is, part of the touch mesh 41 corresponding to the first projection shields the first sub-opening 24a.

Unless otherwise stated, the “distance” between any two parts described in the present disclosure is a minimum distance between the two parts. H1 is equal to H2, that is, the distances from the touch mesh 41 shielding the first sub-opening 24a to the first isolation opening 23a and to the second isolation opening 23b are the same, and the color shift caused by the touch mesh 41 shielding the light emitted by the first light-emitting unit 31a and the second light-emitting unit 31b is avoided or reduced.

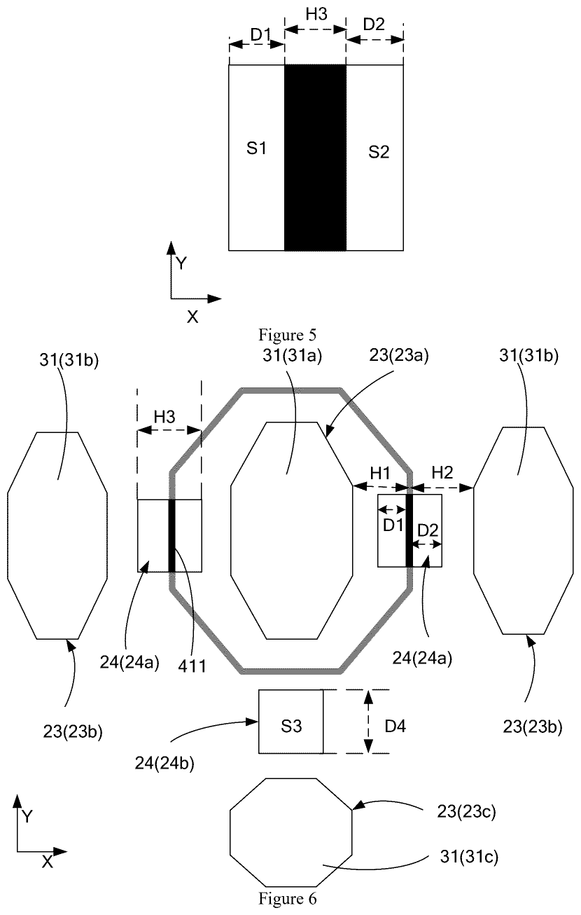

Referring to FIG. 5, in some embodiments, the second projection on a side of the first projection close to the first isolation opening 23a has an area S1, and the second projection on a side of the first projection close to the second isolation opening 23b has an area S2, where S1 is equal to S2.

The first projection overlaps with the second projection, and the second projection is divided, by the first projection, into an area close to the first isolation opening 23a and an area close to the second isolation opening 23b. S1 is equal to S2, that is, through the first sub-opening 24a, the amount of light transmitted between the first isolation opening 23a and the touch mesh 41 is consistent with the amount of light transmitted between the second isolation opening 23b and the touch mesh 41, and thus the uniformity of the light transmitted is improved.

In some embodiments, the second projection on the side of the first projection close to the first isolation opening 23a is axially symmetrical, about the first projection, with the second projection on the side of the first projection close to the second isolation opening 23b, and thus the uniformity of the light transmitted through the first sub-opening 24a from two opposite sides of the touch mesh 41 in the first direction X is improved.

In some embodiments, there is a distance D1 from an orthographic projection, on the array substrate 1, of an edge of the first sub-opening 24a close to the first isolation opening 23a to the first projection, and there is a distance D2 from an orthographic projection, on the array substrate 1, of an edge of the first sub-opening 24a close to the second isolation opening 23b to the first projection, where D1 is equal to D2.

D1 being equal to D2 means that the first sub-opening 24a is arranged centrally between the first isolation opening 23a and the second isolation opening 23b in the first direction X, and thus the uniformity of the transmitted light is improved.

In some embodiments, D1 is 2.5-3 microns. Optionally, D1 is 2.5 microns, 2.8 microns, or 3 microns. D1 is set to be 2.5-3 microns, in order to ensure that there is still sufficient light to be transmitted through the display panel 100 if the first sub-opening 24a is shielded by the touch mesh 41.

In some embodiments, the first projection has a length H3 in the first direction X, and H3 is 3-4 microns.

H3 is set to be 3-4 microns, in order to ensure that the formed touch mesh 41 should not be too thin to break and the touch mesh 41 can stably transmit electrical signals; and in order to ensure that the formed touch mesh 41 is not too thick, such that the first sub-opening 24a has a suitable size on the basis of maintaining a required amount of light transmitted through the first sub-opening 24a shielded by the touch mesh. The length of the first sub-opening 24a in the first direction X is the sum of H3, D1 and D2. Optionally, H3 is 3 microns, 3.5 microns, or 4 microns.

For example, if H3 is 3 microns, D1 is 3 microns and D2 is 3 microns, the length of the first sub-opening 24a in the first direction X is 9 microns.

Referring to FIG. 6, in some embodiments, the plurality of first openings 24 further include a plurality of second sub-openings 24b, an orthographic projection of the second sub-opening 24b on the array substrate 1 is a third projection, and the orthographic projection of the touch mesh 41 on the array substrate 1 does not overlap with the third projection.

The second sub-opening 24b may further be disposed while the first sub-opening 24a is disposed. The orthographic projection of the touch mesh 41 on the array substrate 1 does not overlap with the third projection, that is, the touch mesh 41 does not shield the second sub-opening 24b, such that the light irradiated toward the second sub-opening 24b can all pass through the second sub-opening 24b, and the light transmittance of one side of the third light-emitting unit 31c is improved.

In some embodiments, the third projection has an area S3, the first projection has an area S4, and the second projection has an area S5, where S3 is equal to (S5-S4).

S3 is equal to (S5-S4), that is, when the first sub-opening 24a is shielded by the touch mesh 41, the amount of light transmitted through the first sub-openings 24a is consistent with the amount of light transmitted through the second sub-openings 24b, and thus the uniformity of the light transmitted through each of the first openings 24 is improved.

In some embodiments, the plurality of isolation openings 23 further include a third isolation opening 23c, and the second sub-opening 24b is disposed, in the second direction Y, between the first isolation opening 23a and the third isolation opening 23c which are adjacent.

A plurality of third isolation openings 23c may be disposed at intervals in the first direction X, and the second sub-opening 24b may be disposed, in the second direction Y, between the first isolation opening 23a and the third isolation opening 23c which are adjacent. By forming the second sub-opening 24b on one side of the third isolation opening 23c, the light transmittance of one side of the third light-emitting unit 31c is improved.

The light-emitting units 31 received into the first isolation opening 23a, the second isolation opening 23b and the third isolation opening 23c can emit light of the same color, or at least two of the units can emit light of different colors. For example, the plurality of light-emitting units 31 may further include a third light-emitting unit 31c for emitting third color light, and at least part of the third light-emitting unit 31c is located in the third isolation opening 23c. The third color light may be green light, and the third light-emitting unit 31c is configured to emit green light.

In some embodiments, the third projection has a length D4 in the second direction Y, and D4 is 5-6 microns.

D4 is set to be 5-6 microns, in order to ensure that there is sufficient light to be transmitted through the display panel 100 through the second sub-opening 24b. Optionally, D4 is 5 microns, 5.5 microns, or 6 microns.

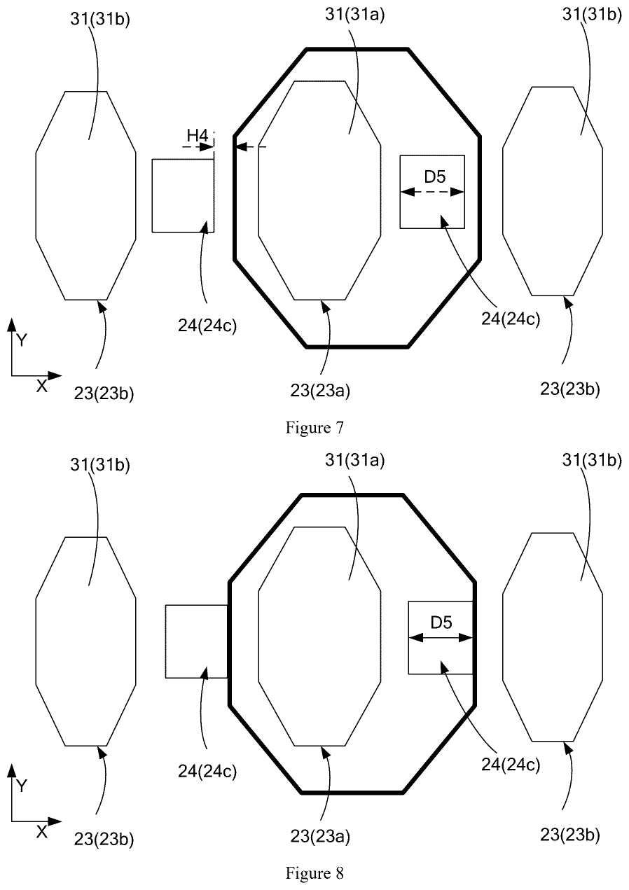

Referring to FIG. 7, in some embodiments, the plurality of first openings 24 include a plurality of third sub-openings 24c, and the orthographic projection of the touch mesh 41 on the array substrate 1 is located within the orthographic projection of the isolation structure 2 on the array substrate 1.

The orthographic projection of the touch mesh 41 on the array substrate 1 is located within the orthographic projection of the isolation structure 2 on the array substrate 1, to prevent or reduce the shielding of the touch layer 4 from light entering the third sub-opening 24c or from light emerging out of the isolation opening 23, and to improve the light transmittance of the display panel 100.

The display panel 100 is provided with the third sub-openings 24c, and the first sub-openings 24a as described above may also be provided.

In some embodiments, an orthographic projection of the touch mesh 41 on the isolation structure 2 is a fourth projection, and the fourth projection surrounds part of a boundary of at least one third sub-opening 24c.

The fourth projection surrounds part of the boundary of the at least one third sub-opening 24c, such that the fourth projection extends along part of the boundary of the third sub-opening 24c and does not surround another part of the boundary of the third sub-opening 24c, increasing the size of the third sub-opening 24c, and improving the light transmittance of the display panel 100. For example, in the embodiment shown in FIG. 7, the touch mesh 41 does not surround a left side boundary, an upper side boundary and a lower side boundary of the third sub-opening 24c on the left, and the fourth projection of the touch mesh 41 surrounds a right side boundary of the third sub-opening 24c on the left, such that the left side boundary of the third sub-opening 24c on the left can be offset or expanded toward the left, and thus the size of the third sub-opening 24c is increased.

In some embodiments, the third sub-opening 24c is located between adjacent isolation openings 23, and part of the boundary of the third sub-opening 24c and the isolation opening 23 don't have the fourth projection distributed between.

The third sub-opening 24c is located between adjacent isolation openings 23, and the adjacent isolation openings 23 and the third sub-opening 24c are separated by the isolation structure 2. By disposing the third sub-opening 24c between the adjacent isolation openings 23, the area of this part can emit light by means of the light-emitting units 31 in the isolation openings 23, and the light can also be transmitted through one side of the display panel 100 through the third sub-opening 24c. The part of the boundary of the third sub-opening 24c and the isolation opening 23 don't have the fourth projection distributed between, such that a space reserved for disposing the touch mesh 41 can be omitted between the third sub-opening 24c and the isolation opening 23, and there is a smaller distance between the third sub-opening 24c and the isolation opening 23, increasing the sizes of the third sub-opening 24c and the isolation opening 23, and thus improving the light transmittance of the display panel 100.

In some embodiments, the plurality of isolation openings 23 include a first isolation opening 23a and a second isolation opening 23b, and the third sub-opening 24c is disposed, in the first direction X, between the first isolation opening 23a and the second isolation opening 23b which are adjacent.

At least part of the first light-emitting unit 31a is located in the first isolation opening 23a, and at least part of the second light-emitting unit 31b is located in the second isolation opening 23b. The plurality of first light-emitting units 31a and the plurality of second light-emitting units 31b may be alternately disposed in the first direction X, and the plurality of third sub-openings 24c may be sequentially disposed at intervals in the first direction X and located between the first light-emitting units 31a and the second light-emitting units 31b which are adjacent, such that the ambient light can be incident from one side of the display panel 100 through the third sub-openings 24c between the first light-emitting units 31a and the second light-emitting units 31b.

In some embodiments, the part of the fourth projection is located between the first isolation opening 23a and the third sub-opening 24c, or the part of the fourth projection is located between the second isolation opening 23b and the third sub-opening 24c.

That is, the touch mesh 41 may extend along a boundary of the third sub-opening 24c close to the first isolation opening 23a, or may extend along a boundary of the third sub-opening 24c close to the second isolation opening 23b, to prevent the touch mesh 41 from shielding the third sub-opening 24c.

In some embodiments, the third sub-opening 24c has a length D5 in the first direction X, and D5 is 5-6 microns.

D5 is set to be 5-6 microns, in order to ensure that sufficient light is transmitted through the display panel 100 through the third sub-opening 24c. D5 is 5 microns, 5.5 microns, or 6 microns.

In some embodiments, a distance from the fourth projection to the third sub-opening 24c in the first direction X is represented by H4, and H4≥0.

The touch mesh 41 and the isolation structure 2 are not arranged in the same layer, such that the fourth projection formed by the touch mesh 41 can be infinitely close to the third sub-opening 24c. As shown in FIG. 8, H4 is equal to 0, such that the touch mesh 41 is close to the third sub-opening 24c on the premise that the touch mesh 41 does not shield the third sub-opening 24c, to decrease the distance between the touch mesh 41 and the third sub-opening 24c, which is conducive to increasing the distance between adjacent isolation openings 23 and increasing the distribution density of the light-emitting units 31.

In some embodiments, the part of the fourth projection is located between the first isolation opening 23a and the third sub-opening 24c, and a minimum distance from the fourth projection to the first isolation opening 23a in the first direction X is greater than or equal to 5 μm; and a minimum distance from the third sub-opening 24c to the second isolation opening 23b in the first direction X is greater than or equal to 5 μm.

The minimum distance from the fourth projection to the first isolation opening 23a in the first direction X is set to be greater than or equal to 5 μm; and the minimum distance from the third sub-opening 24c to the second isolation opening 23b in the first direction X is greater than or equal to 5 μm, such that the isolation structure 2 can be effectively spaced between the third sub-opening 24c and the second isolation opening 23b.

In some embodiments, the part of the fourth projection is located between the second isolation opening 23b and the third sub-opening 24c, and a minimum distance from the fourth projection to the second isolation opening 23b in the first direction X is greater than or equal to 5 μm; and a minimum distance from the third sub-opening 24c to the first isolation opening 23a in the first direction X is greater than or equal to 5 μm.

The minimum distance from the fourth projection to the second isolation opening 23b in the first direction X is set to be greater than or equal to 5 μm; and the minimum distance from the third sub-opening 24c to the first isolation opening 23a in the first direction X is greater than or equal to 5 μm, such that the isolation structure 2 can be effectively spaced between the third sub-opening 24c and the first isolation opening 23a.

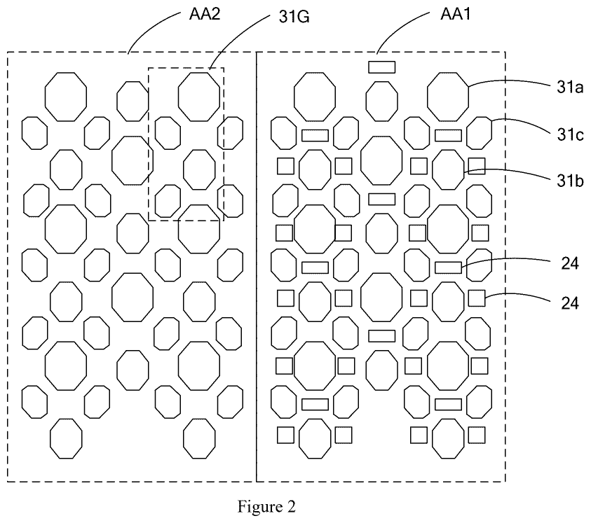

Referring to FIG. 2, in some embodiments, pixels of the light-emitting units 31 in the second active area AA2 are arranged in the same manner as pixels in the first active area AA1.

Pixels in the second active area AA2 are arranged in the same manner as the pixels in the first active area AA1, that is, light-emitting pixel groups are identical in composition and arrangement. The pixels in the second active area AA2 are arranged in the same manner as the pixels in the first active area AA1, such that the first active area AA1 and the second active area AA2 have consistent display effects.

In some embodiments, the orthographic projection of the touch mesh 41 on the isolation structure 2 surrounds at least part of the isolation opening 23, so that the distribution density of the touch mesh 41 is improved.

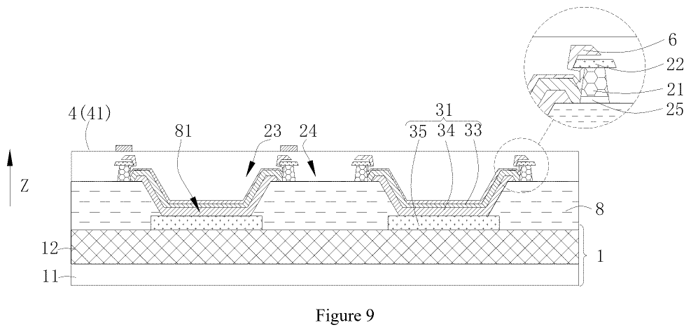

Referring to FIG. 9, in some embodiments, the light-emitting unit 31 includes a second electrode 35, a light-emitting layer 34 and a first electrode 33 sequentially stacked in a direction away from the array substrate 1.

Optionally, the first electrode 33 is electrically connected to the isolation structure 2.

A side of the first electrode 33 close to the array substrate 1 is connected to the light-emitting layer 34, and a first encapsulation layer is located on a side of the first electrode 33 facing away from the array substrate 1. One of the first electrode 33 and the second electrode 35 may be a cathode and the other may be an anode. The first electrode 33 and the second electrode 35 are respectively connected to the light-emitting layer 34 and configured to drive the light-emitting layer 34 to emit light. The first encapsulation layer 6 may cover the side of the first electrode 33 facing away from the array substrate 1, and the first encapsulation layer 6 can reduce or prevent moisture and oxygen from entering the light-emitting units 31, so that the service life of the light-emitting units 31 is prolonged.

An edge of the first electrode 33 may be in lap joint with the isolation structure 2 to electrically connect the first electrode 33 to the isolation structure 2, and adjacent first electrodes 33 may be electrically connected by means of the isolation structure 2.

Optionally, the first electrodes 33 of at least two light-emitting units 31 are electrically connected by means of the isolation structure 2.

In some embodiments, the isolation structure 2 includes a first isolation layer 21 and a second isolation layer 22 which are stacked, the first isolation layer 21 is disposed on a side of the second isolation layer 22 close to the array substrate 1, and an orthographic projection of the first isolation layer 21 on the array substrate 1 is located within an orthographic projection of the second isolation layer 22 on the array substrate 1.

An orthographic projection of the first isolation layer 21 on the array substrate 1 is within an orthographic projection of the second isolation layer 22 on the array substrate, such that an end of the isolation structure 2 away from the array substrate 1 has a larger cross-sectional area, and an end of the isolation structure 2 close to the array substrate 1 has a smaller cross-sectional area. In a direction from the isolation structure 2 to the array substrate 1, the second isolation layer 22 completely shields the first isolation layer 21. For example, the isolation structure 2 has a T-shaped cross section.

When the light-emitting units 31 are prepared, a light-emitting material A used for preparing the light-emitting units 31 may cover the isolation structure 2 by means of evaporation technology. Since the second isolation layer 22 shields the first isolation layer 21, the light-emitting material A used for preparing the light-emitting units 31 has a large drop at an edge of the second isolation layer 22, and it is unlikely to connect the light-emitting material A falling into the isolation opening 23 and the light-emitting material A falling on the second isolation layer 22. Accordingly, breakage occurs, and pieces of light-emitting material A spaced apart from each other are formed in the adjacent isolation openings 23. The first encapsulation layer may be prepared on the light-emitting material A, a photoresist is disposed on a side of the first encapsulation layer facing away from the array substrate, the photoresist is used as a mask to remove the light-emitting material A falling on the second isolation layer 22 as required, and during removal, the first encapsulation layer may protect the light-emitting material A falling within the isolation opening 23. Compared with the prior art that a light-emitting layer 34 is prepared by means of high-precision mask evaporation, in the present disclosure, by providing the first isolation layer 21 and the second isolation layer 22, the light-emitting units 31 in the isolation openings 23 can be prepared without using a high-precision metal mask, so that the cost of preparing the high-precision metal mask is omitted. Compared with the light-emitting layer 34 prepared by preparing a high-precision metal mask for evaporation, it is easier to directly prepare a high-precision isolation structure 2, so that the structure of the display panel 100 provided by the present disclosure has low requirements for a preparation process, and the prepared display panel 100 has good consistency. The light-emitting material A may be a complex containing an indium element.

In some embodiments, the area of an orthographic projection of a surface, facing away from the array substrate 1, of the second isolation layer 22 on the array substrate is less than the area of an orthographic projection of a surface, close to the array substrate 1, of the second isolation layer 22 on the array substrate.

The second isolation layer 22 extends outwardly relative to the first isolation layer 21 by a predetermined distance, that is, the area of the orthographic projection of the surface, facing away from the array substrate 1, of the second isolation layer 22 on the array substrate is less than the area of the orthographic projection of the surface, close to the array substrate 1, of the second isolation layer 22 on the array substrate 1, such that the second isolation layer 22 has an inclined ramp structure to define a pattern of the light-emitting layer 34 by means of the second isolation layer 22.

In some embodiments, the cross-sectional area of the second isolation layer 22 gradually decreases in a direction away from the array substrate 1.

Optionally, a cross section of the second isolation layer 22 is in the shape of a trapezoid with a base facing the array substrate 1, such that the second isolation layer 22 has a ramp surface, which is conducive to the breakage of a preparation material at a partition edge, allowing part of the preparation material to be located on the second isolation layer 22 and part of the preparation material to be located in the isolation opening 23.

In some embodiments, the area of an orthographic projection of a surface, facing away from the array substrate 1, of the first isolation layer 21 on the array substrate is less than the area of the orthographic projection of the surface, close to the array substrate 1, of the second isolation layer 22 on the array substrate.

That is, the second isolation layer 22 extends outwardly relative to the first isolation layer 21 to limit the patterns of the first electrode 33 and the light-emitting layer 34 by means of the second isolation layer 22. The second isolation layer 22 has a greater area than the first isolation layer 21 and completely covers the first isolation layer 21. In this case, the first isolation layer 21 is recessed relative to the second isolation layer 22 in a direction away from the isolation opening 23. When the light-emitting units 31 are prepared, at least part of the material used for preparing the light-emitting units 31 has a large drop at an edge of the isolation structure 2, and the first isolation layer 21 is recessed, so that the material used for preparing the light-emitting units 31 is unlikely to be continuous on an outer side of the isolation structure 2, and accordingly a breakage occurs to form the light-emitting units 31 which are isolated from each other.

In some embodiments, the isolation structure 2 includes a third isolation layer 25, the third isolation layer 25 is located on a side of the first isolation layer 21 close to the array substrate 1, and the orthographic projection of the first isolation layer 21 on the array substrate 1 is located within an orthographic projection of the third isolation layer 25 on the array substrate 1. The isolation structure 2 may have an I-shaped cross section.

Optionally, the area of the orthographic projection of the first isolation layer 21 on the array substrate 1 is less than the area of the orthographic projection of the third isolation layer 25 on the array substrate 1.

The first isolation layer 21 may have a trapezoidal cross section to increase the size of the isolation opening 23. The cross-section of the first isolation layer 21 may be in the shape of a right trapezoid, such that the second isolation layer 22 can be securely supported, and the first isolation layer 21 and the second isolation layer 22 have a small contact surface area.

Optionally, the orthographic projection of the first isolation layer 21 on the array substrate 1 is located within the orthographic projection of the third isolation layer 25 on the array substrate 1, so that the third isolation layer 25 can stably support the first isolation layer 21, thereby achieving a recessed configuration of the first isolation layer 21 relative to the second isolation layer 22 in a direction away from a central axis of the isolation opening 23, and facilitating the breakage of a light-emitting device layer at the isolation structure 2. Etching waste produced by etching the first isolation layer 21 falls on the third isolation layer 25, thereby facilitating cleaning.

In some embodiments, the first isolation layer 21 includes a conductive material, the edge of the first electrode 33 of the light-emitting unit 31 is in lap joint with the first isolation layer 21.

The edge of the first electrode 33 is in lap joint with the first isolation layer 21, so that the first isolation layer 21 can supply power to the first electrode 33, and also enable adjacent first electrodes 33 to conduct electricity, so as to form a surface electrode with the entire surface being electrically conductive.

In some other embodiments, the third isolation layer 25 includes a conductive material, and the edge of the first electrode 33 of the light-emitting unit 31 is in lap joint with the third isolation layer 25.

The edge of the first electrode 33 is in lap joint with the third isolation layer 25, so that the third isolation layer 25 can supply power to the first electrode 33, and also enable adjacent first electrodes 33 to conduct electricity, so as to form a surface electrode with the entire surface being electrically conductive.

In some embodiments, a material of the first isolation layer 21 includes aluminum, gold, or copper; a material of the second isolation layer 22 includes titanium or molybdenum; and a material of the third isolation layer 25 includes molybdenum or titanium.

Optionally, the material of the third isolation layer 25 includes molybdenum metal; the material of the first isolation layer 21 includes aluminum metal; and the material of the second isolation layer 22 includes titanium metal. Optionally, the material of the third isolation layer 25 includes titanium metal; the material of the first isolation layer 21 includes aluminum metal; and the material of the second isolation layer 22 includes titanium metal.

Optionally, the isolation structure 2 is in the form of a mesh, and the isolation openings 23 are arranged in an array to improve the light emission uniformity of the light-emitting units 31 provided.

In some embodiments, the display panel 100 further includes a pixel defining layer 8 disposed between the array substrate 1 and the isolation structure 2, the pixel defining layer 8 includes pixel openings 81, and the pixel openings 81 communicate with corresponding isolation openings 23.

The pixel defining layer 8 includes a pixel defining portion, the pixel defining portion encloses the pixel openings 81, and an orthographic projection of the pixel opening 81 on the array substrate 1 is located within the range of an orthographic projection of the isolation opening 23 on the array substrate 1.

At least part of the light-emitting unit 31 may be disposed within the pixel opening 81 to achieve the light emission and display of the display panel 100, and the pixel opening 81 may be disposed corresponding to the isolation opening 23.

In some embodiments, the isolation structure 2 is disposed on a side of the pixel defining layer 8 facing away from the array substrate 1. In one embodiment, the pixel defining layer 8 is provided with a clearance opening, and the isolation structure 2 is located in the clearance opening.

The isolation structure 2 may be directly disposed on the side of the pixel defining layer 8 facing away from the array substrate 1, and the isolation structure 2 is supported by means of the pixel defining layer 8.

The orthographic projection of the pixel opening 81 on the array substrate 1 may be located within the orthographic projection of the isolation opening 23 on the array substrate. The area of the isolation opening 23 may be greater than the area of the pixel opening 81, so that the effect of the isolation structure 2 on a light output viewing angle of the light-emitting device layer can be reduced.

Optionally, a plurality of pixel openings 81 are provided. The plurality of pixel openings 81 are distributed at intervals, and the isolation structure 2 may be disposed on at least part of the pixel defining portion between two adjacent pixel openings 81. Optionally, the isolation structure 2 may surround at least part of the pixel opening 81.

In some embodiments, at least part of the first electrode 33 extends to a side of the pixel defining layer 8 away from the array substrate to be in electrical contact with the third isolation layer 25 or the first isolation layer 21 in the isolation structure 2, and the third isolation layer 25 or the first isolation layer 21 of the isolation structure 2 may connect adjacent first electrodes 33 or connect the first electrodes 33 to other circuits.

The embodiment in a second aspect of the present disclosure further provides a display panel 100. The display panel 100 includes an array substrate 1, an isolation structure 2, a light-emitting functional layer and a touch layer 4, where the isolation structure 2 is disposed on one side of the array substrate 1, and the isolation structure 2 is provided with a plurality of isolation openings 23 and a plurality of first openings 24; the light-emitting functional layer includes a plurality of light-emitting units 31, and at least part of the light-emitting unit 31 is disposed in the isolation opening 23; and the touch layer 4 is disposed on a side of the isolation structure 2 facing away from the array substrate 1, the touch layer 4 includes a plurality of touch meshes 41, orthographic projections of the touch meshes 41 on the array substrate do not overlap with orthographic projections of the light-emitting units 31 on the array substrate 1, and the orthographic projections of the touch meshes 41 in the first active area AA1 on the array substrate 1 partially overlap with orthographic projections of part of the first openings 24 on the array substrate.

In this embodiment, the light transmittance of the display panel 100 is improved by providing the first openings 24; and the orthographic projections of the touch meshes 41 on the array substrate 1 partially overlap with the orthographic projections of the first sub-openings 24a on the array substrate 1, that is, the touch meshes 41 partially shield the first sub-openings 24a, such that part of light irradiated into the display panel 100 is shielded by the touch meshes 41, to give place to the isolation openings 23 and to prevent the touch meshes 41 from shielding the isolation openings 23.

In some embodiments, the display panel 100 includes a first active area AA1 and a second active area AA2, the light transmittance of the first active area AA1 is greater than the light transmittance of the second active area AA2, and the first openings 24 are distributed in the first active area AA1; and the orthographic projections of the touch meshes 41 in the first active area AA1 on the array substrate 1 partially overlap with the orthographic portions of part of the first openings 24 on the array substrate 1.

The light transmittance of the first active area AA1 is improved by providing the first openings 24. The orthographic projections of the touch meshes 41 located in the first active area AA1 on the array substrate 1 are configured to partially overlap with the orthographic projections of part of the first openings 24 on the array substrate 1, thereby giving place to the isolation openings 23, and preventing the touch meshes 41 from shielding the isolation openings 23.

The display panel 100 provided by the embodiments in the second aspect of the present disclosure may include all or part of the embodiments of the display panel 100 in the first aspect, which will not be repeated herein.

An embodiment in a third aspect of the present disclosure further provides a display device, including a display panel 100 of any one of the above embodiments in the first aspect and the second aspect. Since the display device provided by the embodiment in the third aspect of the present disclosure includes the display panel 100 of any one of the above embodiments in the first aspect and the second aspect, the display device provided by an embodiment in a third aspect of the present disclosure has the beneficial effects of the display panel 100 of any one of the above embodiments in the first aspect and the second aspect, which will not be repeated herein.

The display device in the embodiments of the present disclosure includes, but is not limited to, devices having a display function, such as a mobile phone, a personal digital assistant (PDA), a tablet computer, an e-book reader, a television, an access control system, a smart fixed-line telephone, or a console.

When the terms “comprise”, “have”, and “include” are used as described herein, unless otherwise clearly defined, for example, expressions “only” and “composed of . . . ”, another component may further be added. Unless otherwise mentioned, the singular form may include plural forms and should not be construed as the number thereof being one.

The embodiments may be combined in any manner. For the purpose of simplicity in description, not all possible combinations of the features in the above-described embodiments are described. However, as long as the combinations of these features do not conflict with each other, the combinations shall all fall within the scope of the description.

The above embodiments merely represent several implementations of the present disclosure, giving specifics and details thereof, but should not be understood as limiting the scope of patent of the present disclosure. Several alterations and improvements may be made without departing from the spirit of the present disclosure and these would all fall within the scope of protection of the present disclosure. Therefore, the scope of protection of the present patent application shall be in accordance with the appended claims.

The embodiments of the present disclosure as described above neither set forth all the details, nor do they limit the present disclosure to only the described specific embodiments. Apparently, many modifications and variations can be made in light of the above description. The embodiments are selected and described in this specification to better explain the principles and practical applications of the present disclosure. The present disclosure is limited only by the claims and all the scopes and equivalents thereof.

1. A display panel, comprising a first active area and a second active area, a light transmittance of the first active area being greater than a light transmittance of the second active area, and the display panel comprising:
an array substrate;
an isolation structure disposed on one side of the array substrate, a plurality of isolation openings and a plurality of first openings being formed in the isolation structure, and the first openings being distributed in the first active area;
a light-emitting functional layer comprising a plurality of light-emitting units, at least part of the light-emitting unit being disposed in the corresponding isolation opening; and
a touch layer disposed on a side of the isolation structure facing away from the array substrate, the touch layer comprising a plurality of touch meshes, and orthographic projections of the touch meshes in the first active area on the array substrate forming the same patterns as orthographic projections of the touch meshes in the second active area on the array substrate.

2. The display panel according to claim 1, wherein the plurality of first openings comprise a plurality of first sub-openings, and the orthographic projections of the touch meshes located in the first active area on the array substrate partially overlap with orthographic projections of the first sub-openings on the array substrate.

3. The display panel according to claim 2, wherein the plurality of isolation openings comprise a first isolation opening and a second isolation opening; and the first sub-opening is disposed between the first isolation opening and the second isolation opening which are adjacent in a first direction.

4. The display panel according to claim 3, wherein the orthographic projection of the touch mesh located in the first active area on the array substrate comprises a first projection, the orthographic projection of the first sub-opening on the array substrate is a second projection, and the first projection is located within the second projection; and
there is a distance H1 from the first projection to the first isolation opening, and there is a distance H2 from the first projection to the second isolation opening, wherein H1 is equal to H2.

5. The display panel according to claim 4, wherein the second projection on a side of the first projection close to the first isolation opening has an area S1, and the second projection on a side of the first projection close to the second isolation opening has an area S2, wherein S1 is equal to S2; and
the second projection on the side of the first projection close to the first isolation opening is axially symmetrical, about the first projection, with the second projection on the side of the first projection close to the second isolation opening.

6. The display panel according to claim 4, wherein there is a distance D1 from an orthographic projection, on the array substrate, of an edge of the first sub-opening close to the first isolation opening to the first projection, and there is a distance D2 from an orthographic projection, on the array substrate, of an edge of the first sub-opening close to the second isolation opening to the first projection, wherein D1 is equal to D2.

7. The display panel according to claim 4, wherein the plurality of first openings further comprise a plurality of second sub-openings, an orthographic projection of the second sub-opening on the array substrate is a third projection, and the orthographic projection of the touch mesh on the array substrate does not overlap with the third projection; and the third projection has an area S3, the first projection has an area S4, and the second projection has an area S5, wherein S3 is equal to (S5-S4).

8. The display panel according to claim 1, wherein the plurality of first openings comprise a plurality of third sub-openings, and the orthographic projection of the touch mesh on the array substrate is located within the orthographic projection of the isolation structure on the array substrate;
an orthographic projection of the touch mesh on the isolation structure is a fourth projection, and the fourth projection surrounds part of a boundary of at least one third sub-opening; and
the third sub-opening is located between adjacent isolation openings, and part of the boundary of the third sub-opening and the isolation opening don't have the fourth projection distributed between.

9. The display panel according to claim 8, wherein the plurality of isolation openings comprise a first isolation opening and a second isolation opening, and the third sub-opening is disposed between the first isolation opening and the second isolation opening which are adjacent in a first direction; and
part of the fourth projection is located between the first isolation opening and the third sub-opening, or part of the fourth projection is located between the second isolation opening and the third sub-opening.

10. The display panel according to claim 9, wherein a distance from the fourth projection to the third sub-opening in the first direction is represented by H4, and H4≥0.

11. The display panel according to claim 9, wherein the part of the fourth projection is located between the first isolation opening and the third sub-opening, and a minimum distance from the fourth projection to the first isolation opening in the first direction is greater than or equal to 5 μm; a minimum distance from the third sub-opening to the second isolation opening in the first direction is greater than or equal to 5 μm;
or the part of the fourth projection is located between the second isolation opening and the third sub-opening, and a minimum distance from the fourth projection to the second isolation opening in the first direction is greater than or equal to 5 μm; and
a minimum distance from the third sub-opening to the first isolation opening in the first direction is greater than or equal to 5 μm.

12. The display panel according to claim 1, wherein pixels of the light-emitting units in the second active area are arranged in the same manner as pixels in the first active area; and
an orthographic projection of the touch mesh on the isolation structure surrounds at least part of the isolation opening.

13. The display panel according to claim 1, wherein the light-emitting unit comprises a second electrode, a light-emitting layer and a first electrode sequentially stacked in a direction away from the array substrate, and the first electrode is electrically connected to the isolation structure; and
the first electrodes of at least two light-emitting units are electrically connected by means of the isolation structure.

14. The display panel according to claim 1, wherein the isolation structure comprises a first isolation layer and a second isolation layer which are stacked, the first isolation layer is disposed on a side of the second isolation layer close to the array substrate, and an orthographic projection of the first isolation layer on the array substrate is located within an orthographic projection of the second isolation layer on the array substrate.

15. A display panel, comprising:
an array substrate;
an isolation structure disposed on one side of the array substrate, a plurality of isolation openings and a plurality of first openings being formed in the isolation structure;
a light-emitting functional layer comprising a plurality of light-emitting units, at least part of the light-emitting unit being disposed in the corresponding isolation opening; and
a touch layer disposed on a side of the isolation structure facing away from the array substrate, the touch layer comprising a plurality of touch meshes, and orthographic projections of the touch meshes on the array substrate partially overlapping with an orthographic projection of at least one first opening on the array substrate.

16. The display panel according to claim 15, wherein the display panel comprises a first active area and a second active area, a light transmittance of the first active area is greater than a light transmittance of the second active area, and the first openings are distributed in the first active area; and
orthographic projections of the touch meshes located in the first active area on the array substrate partially overlap with orthographic projections of the first openings on the array substrate.

17. The display panel according to claim 16, wherein the plurality of isolation openings comprise a first isolation opening and a second isolation opening, the plurality of first openings comprise a plurality of first sub-openings, and the first sub-opening is disposed between the first isolation opening and the second isolation opening which are adjacent in a first direction;
the orthographic projection of the touch mesh located in the first active area on the array substrate comprises a first projection, an orthographic projection of the first sub-opening on the array substrate is a second projection, and the first projection is located within the second projection; and
there is a distance H1 from the first projection to the first isolation opening, and there is a distance H2 from the first projection to the second isolation opening, wherein H1 is equal to H2.

18. The display panel according to claim 17, wherein the second projection on a side of the first projection close to the first isolation opening has an area S1, and the second projection on a side of the first projection close to the second isolation opening has an area S2, wherein S1 is equal to S2; and
the second projection on the side of the first projection close to the first isolation opening is axially symmetrical, about the first projection, with the second projection on the side of the first projection close to the second isolation opening.

19. The display panel according to claim 17, wherein there is a distance D1 from an orthographic projection, on the array substrate, of an edge of the first sub-opening close to the first isolation opening to the first projection, and there is a distance D2 from an orthographic projection, on the array substrate, of an edge of the first sub-opening close to the second isolation opening to the first projection, wherein D1 is equal to D2.

20. A display device, comprising:
a display panel, comprising:
a first active area and a second active area, a light transmittance of the first active area being greater than a light transmittance of the second active area, and the display panel comprising:
an array substrate;
an isolation structure disposed on one side of the array substrate, a plurality of isolation openings and a plurality of first openings being formed in the isolation structure, and the first openings being distributed in the first active area;
a light-emitting functional layer comprising a plurality of light-emitting units, at least part of the light-emitting unit being disposed in the corresponding isolation opening; and
a touch layer disposed on a side of the isolation structure facing away from the array substrate, the touch layer comprising a plurality of touch meshes, and orthographic projections of the touch meshes in the first active area on the array substrate forming the same patterns as orthographic projections of the touch meshes in the second active area on the array substrate.
